(19) United States
(12) Patent Application Publication
(10) Pub. No.: US 2025/0271466 A1
(43) Pub. Date: Aug. 28, 2025

(54) Adjustable Probe Tip

(71) Applicant: PMK Mess- und Kommunikationstechnik, GmbH, Bad Soden am Taunus (DE)

(72) Inventors: Michael J Mende, Portland, OR (US); Mark Heimann, Bad Soden am Taunus (DE); Richard Booman, Lake Oswego, OR (US); Philipp Palffy-Daun-Seiler, Bad Soden am Taunus (DE); Michael Engels, Krefeld (DE); Nadja Laeaeperi, Koenigstein im Taunus (DE); Benno Jacobs, Duisburg (DE); Michael D Stevens, Hillsboro, OR (US); Nicolas Frabasile, Hattersheim am Main (DE); Peter Hildenhagen, Alpen (DE); Kai Klein, Neu-Anspach (DE); Jurij Weber, Schwalbach am Taunus (DE); Iris Zimmermann, Mainz (DE); Juergen Trueller, Gernheim (DE); Thomas Podrebersek, Rheurdt (DE); Michael Eube, Xanten (DE); Frank Pannes, Duisburg (DE); Matthew M Mende, Portland, OR (US)

(21) Appl. No.: 18/586,534

(22) Filed: Feb. 25, 2024

(51) Int. Cl. G01R 1/067; G01R 1/04; G01R 31/319

(52) U.S. Cl. CPC G01R 1/06705; G01R 1/0466; G01R 31/31905

(57) ABSTRACT

An adjustable probe tip for testing and measuring differential signals on a DUT, the probe tip features an electrically conductive support layer and an electrically conductive double-barrel housing. The double barrel housing has a test barrel and an reference barrel. The test barrel is mountable to a recessed portion of the support layer in an axially secured and rotatable fashion.

### FIELD OF THE DISCLOSURE

The present invention pertains to the field of test and measurement probes, and more particularly, to an adjustable, shielded test probe tip for measuring differential signals on a device under testing (DUT).

### BACKGROUND OF THE DISCLOSURE

Test and measurement probes are crucial tools for analyzing and evaluating signals from DUTs. Typically, such probes are utilized to connect with signal reference interfaces on the DUT for transferring test and reference signals to the test and measurement system. However, the performance of these probes can be compromised, for example by parasitic capacitances among probe components, which may distort the probe's frequency response and alter the test signals. Moreover, the proximity of probe elements can lead to unwanted current induction between adjacent DUT pins, introducing noise that was not originally present in the DUT and adversely affecting the test signal quality.

The current generation of probe tips often falls short in adaptability, especially when faced with diverse test point configurations. This limitation can lead to unsafe testing conditions, intermittent connections, difficult access to test points, and measurement inaccuracies.

### SUMMARY OF THE DISCLOSURE

What is needed is an adjustable probe tip for testing and measuring differential signals on a DUT, to improve versatility in adapting to varying test point configurations, and to improve measurement accuracy.

In one embodiment, the adjustable probe tip has an electrically conductive support layer and an electrically conductive double-barrel housing. The conductive double-barrel housing has a test barrel and an reference barrel. The test barrel is mountable to a recessed portion of the support layer in an axially secured and rotatable fashion such that the test barrel is axially mounted to a recessed portion of the support layer and is rotatable around a longitudinal axis of the support layer. The reference barrel has a reference socket on a proximal end of the probe tip to establish a reference signal path from the reference socket to the support layer.

In another embodiment, the probe tip has an electrically insulated cap on the proximal end of the probe tip which contains a signal socket to establish a test signal path inside the support layer.

### BRIEF DESCRIPTION OF THE DRAWINGS

The accompanying drawings that are incorporated in and constitute a part of this specification illustrate several embodiments of the disclosure. Together with the description, they serve to explain the principles of the disclosure.

FIG. 1 is a partial cross-sectional perspective view of an example adjustable probe tip.

FIG. 2 is a cross-section side view of an example adjustable probe tip.

FIG. 3 is a partial cross-sectional side view of an example adjustable probe tip.

FIG. 4 is a partial cross-sectional side view of an example adjustable probe tip, shown as a partially exploded view.

FIG. 5 is a partial cross-sectional perspective view of an example adjustable probe tip, shown as an exploded view.

FIG. 6 is a cross-sectional side view of an exemplary adjustable probe tip in combination with a probe tip cable, a probe head adapter, and a DUT in a disengaged configuration.

FIG. 7 is a partial cross-sectional side view of an exemplary adjustable probe tip and a DUT in an engaged configuration.

### REFERENCE NUMERALS OF THE DRAWINGS

1 Adjustable probe tip
2 DUT abutment surface
3 Proximal end
4 Proximal end surface of the support layer
5 Distal end
6 Outer surface of the support layer
7 Support layer
8 Inner surface of the support layer
9 Recessed portion
10 Ring portion of the support layer
11 Conductive double-barrel housing
12 Test barrel
13 Insulated double-barrel housing
14 Reference barrel
15 Cap
16 Circumferential lip
17 Through-hole opening
19 Longitudinal axis
20 Reference barrel axis
21 Reference receptacle
22 Adjustment angle
23 Pitch
25 Test receptacle
27 Reference socket
29 Test socket
31 Attenuator device
33 Insulation layer
35 Outer layer
37 Test signal coupler
39 Probe tip cable
41 Reference signal coupler
43 Friction-fit portion
45 Stepped cylindrical portion
46 Abutment surface
47 Beveled test opening
49 Radially protruding portion
51 Beveled reference opening
53 Longitudinal slit
55 Probe head adapter
57 Test signal pin
59 Reference signal pin
61 Device under Testing DUT

### DETAILED DESCRIPTION

The present disclosure generally provides for probe tips used for testing and measuring of differential signals on a DUT. One objective is to provide a probe tip that is versatilely applicable in a wide range of DUT test points in an ergonomic manner while accurately resolving small differential signals at high bandwidths. The probe tip of the disclosure can be connected to the DUT in a hard-to-access area without having to twist or bend a probe tip cable in order to reach a square pin interface.

The adjustable probe tip is suitable for retrieving a test signal and a reference signal from a dedicated test interface provided on a DUT. Signal transmission in the adjustable probe tip may be a shielded analog signal transmission. The analog test input signal may be a high-frequency signal such as a radio frequency signal.

In the context of the present disclosure, the term, “test signal,” is to be understood as signal to be tested/measured, referring to the variable, e.g. oscillating, signal to be measured, as provided by the dedicated test signal output of test point on the DUT, e.g. its dedicated test signal pin. The term, “reference signal,” is to be understood as the reference signal as provided by the dedicated reference signal output of test point on the DUT, e.g. the reference signal pin.

Test points on the DUT may comprise signal pins such as square pins as interfaces for outputting test and reference signals from the DUT. Square pins constitute the male part of a connector, which is to be connected to a square pin socket. A square pin interface on a DUT may comprise a test-signal carrying square pin and one or more reference-signal carrying square pins. The gap between the test square pin and an associated reference square pin is called “pitch.” In the industry, different pitch sizes are used and well documented in industry standards.

In the following sections, detailed descriptions of examples and methods of the disclosure will be given. The description of both preferred and alternative examples is exemplary only, and it is understood that to those skilled in the art that variations, modifications, and alterations may be apparent. It is therefore to be understood that the examples do not limit the broadness of the aspects of the underlying disclosure as defined by the claims.

### DETAILED DESCRIPTIONS OF THE DRAWINGS

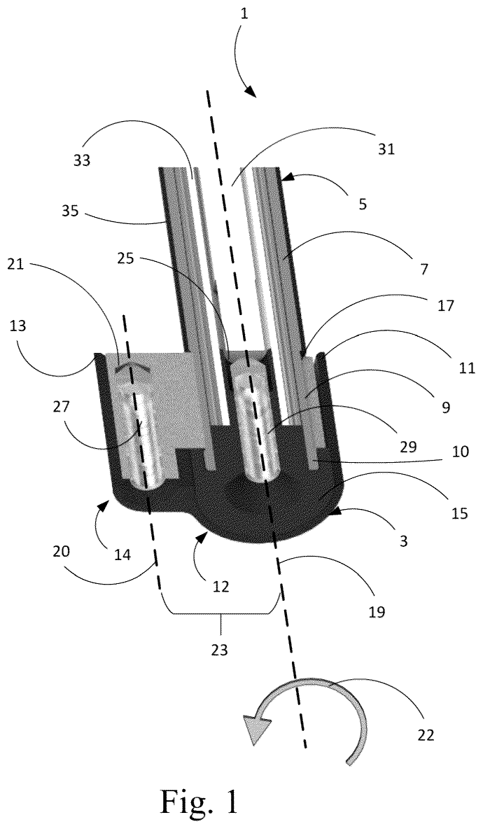

Referring to FIG. 1, a partial cross-sectional perspective view of an example adjustable probe tip 1 is shown. The adjustable probe tip 1 and corresponding components are discussed in terms of proximal ends and distal ends. As used herein, the term distal indicates the portion of a component closest to a test system, when engaged, and the term proximal indicates the portion of a component closest to a DUT circuit board, when engaged. Hence, the probe tip 1 comprises a proximal end 3 and a distal end 5. The probe tip 1 is designed to accept differential signals or other signal pairs. The probe tip 1 comprises a signal input for a test signal and a reference input for a reference signal. The differential signal is a difference between test signal values and reference signal values. For example, the difference between a positive voltage and a negative voltage.

The adjustable probe tip 1 comprises a support layer 7, extending from the distal end 5 to the proximal end 3. The support layer 7 comprises a tubular body that has electrically conductive properties. On the proximal end 3 of the probe tip 1, the support layer 7 comprises a recessed portion 9, providing a ring-shaped recess the outer mantle surface of the support layer 7. The recessed portion 9 is provided such that a ring portion 10 remains on the proximal end of the support layer 7. The adjustable probe tip 1 further comprises a conductive double-barrel housing 11, an insulated double-barrel housing 13, and a cap 15. The conductive double-barrel housing 11 comprises a through-hole opening 17 having an inner mantle surface 19, constituting its first barrel, the test barrel 12. When the conductive double-barrel housing 11 engages with the recessed portion 9 via the through-hole opening 17, the conductive double-barrel housing 11 can revolve around a longitudinal axis 19 of the support layer 7, maintaining an electrical connection between the conductive double-barrel housing 11 and the support layer 7. The conductive double-barrel housing 11 also comprises a cylindrical receptacle 21, constituting the second barrel, the reference barrel 14. The reference barrel 14 is oriented along the reference barrel axis 20, which runs parallel to the longitudinal axis 19 at a pitch 23. The insulating double-barrel housing 13 is provided as an additional layer wrapped around the conductive double-barrel housing 11. On the proximal end 3, the support layer 7 is sealed by the cap 15, which is friction-fitted to the support layer 7. Towards the proximal end 3, the cap 15 ends flush with the insulating double-barrel housing 13. On its inside, the cap 15 comprises a test receptacle 25. The cap 15 is releasably mountable to the support layer 7.

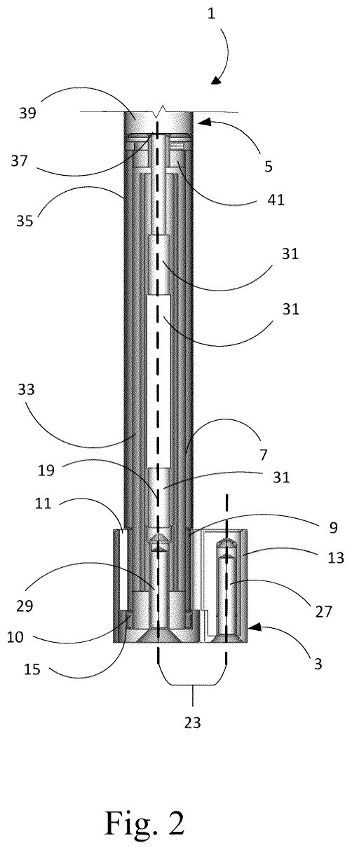

The adjustable probe tip 1 provides two electrically conductive paths: a reference signal path and a test signal path. The reference signal path extends from a reference socket 27 placed inside the cylindrical receptacle 21, continues via the electrically conductive double-barrel housing 11, and proceeds to the support layer 7 via the recessed portion 9. The test signal path extends from a signal socket 29 placed inside the test receptacle 25 of the cap 15, see also FIG. 2 for more information pertaining to the reference and test signal paths.

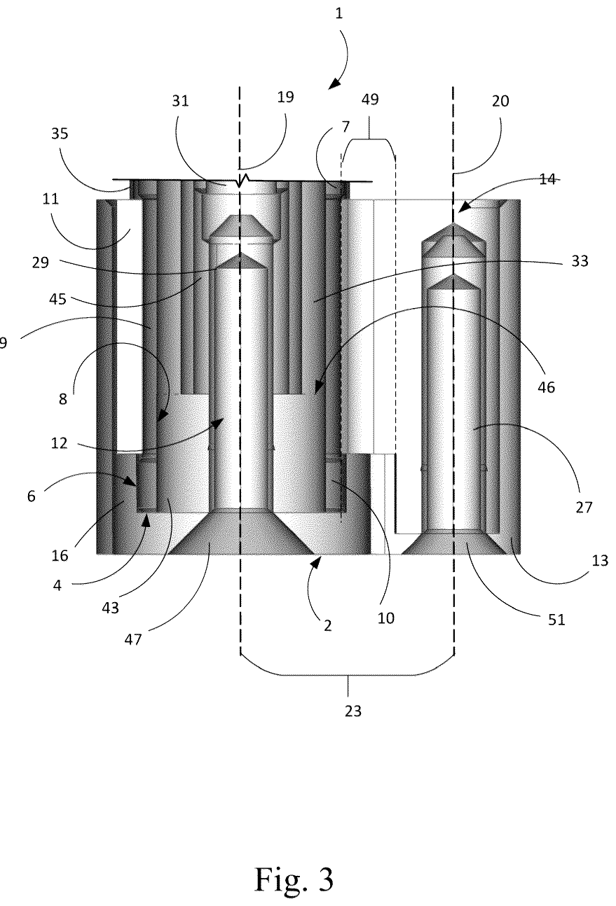

Inside the support layer 7, an attenuator device 31 is provided, which is in electrical contact with the cylindrical receptacle 25. To electrically insulate the reference signal path from the test signal path, an insulation layer 33 is provided between the attenuator device 31 and the support layer 7. The insulation layer 33 comprises electrically insulating material properties and comprises a tube, nested inside the support layer 7, and abutting the cap 15 in the longitudinal direction, see also FIG. 3. The cap 15 may arrest the insulation layer 33 and the attenuator device 31 in the longitudinal direction. The support layer 7 further comprises an outer layer 35 having electrically insulating material properties. The cap 15, the insulating double-barrel housing 13, and the outer layer 35 may comprise or may be made of an electrically insulating material. Specifically, they can be made of or comprise the same electrically insulating material.

The reference socket 27 and the signal socket 29 may be configured to accommodate square pins of a DUT in an electrically shielded manner. With the adjustable probe tip 1, it is possible to adjust the reference socket 27 around the signal socket 29 by an adjustment angle 22 and a constant radius representing the pitch 23. This allows reaching a wide variety of test points of a given pitch, without having to twist or bend or twist the probe tip. The adjustment angle may be anything between 0 and 360 degrees and may have a positive or negative orientation.

Referring now to FIG. 2, a cross-sectional side view of an example adjustable probe tip is shown in combination with a probe tip cable. The test barrel of the double-barrel housing is rotatable around a longitudinal axis of the support layer, and the reference barrel orbits about the longitudinal axis in an adjustment angle at distance equal to pitch 23. In addition to the signal socket 29 and the attenuator device 31, the test signal path further comprises a test signal coupler 37, which is provided on the distal end 5 of the probe tip 1. At the test signal coupler 37, the test signal is coupled to the probe tip cable 39. The reference signal path further comprises a reference signal coupler 41, which is provided on the distal end 5 of the probe tip 1, coupling the reference signal from the attenuator device 31 into the probe tip cable 39.

Referring now to FIG. 3, a partial cross-sectional side view of an example adjustable probe tip 1 is shown. The supporting layer 7 acts as an electrical conductor, to which the conductive double-barrel housing 11 may be coupled. The supporting layer 7 also acts as a housing, accommodating the signal path components on its inside. The supporting layer 7 also provides a locking interface via its recessed portion 9, which allows locking the conductive double-barrel housing 11 in a longitudinal direction 19, whilst allowing the conductive double-barrel housing to be revolved about the longitudinal axis 19. The ring portion 10 allows to positively lock the conductive double-barrel housing 11 in an axial direction along the longitudinal axis 19. The outer layer 35 is provided as a coating, cladding, or layer, covering the support layer 7. The conductive double-barrel housing 11 protrudes radially beyond the support layer 7. The outer layer 35 only covers the support layer 7 in the areas that are not the recessed portion 9 and the ring portion 10. The supporting layer 7 also provides the support structure for the cap 15.

The cap 15 is friction-fitted to the proximal opening of the support layer 7. The friction-fit is achieved both along an inner surface 8 of the support layer 7 and along an outer surface 6 of the support layer 7. On the inner surface 8 of the support layer 7, the cap 15 extends beyond the recess portion 9. The cap 15 has a friction-fit portion 43, and a stepped cylindrical portion 45. The friction-fit portion 43 engages with the inside surface 8 of the support layer 7. The stepped cylindrical portion 45 protrudes along the test of the cap 15, forming the test receptacle 25, which accommodates the signal socket 29. The stepped cylindrical portion 45 also provides an abutment surface 46 for the insulating layer 33 in the direction of the longitudinal axis 19. The cylindrical receptacle 25 is configured to receive the signal socket 29 flush with the proximal end of the support layer 7. Beyond the proximal end of the supporting layer 7, the cap 15 has a thickness extending in the longitudinal direction and comprises a beveled opening 47, tapering from the proximal end across the entire thickness of the cap 15 and forming an opening to the test receptacle 25. The cap 15 further comprises a circumferential lip 16, engaging with an outer surface of the support layer 7 along the ring portion 10. The circumferential lip 16, which is configured to extend along the ring portion 10 in such a way that the cap 15 surrounds the inner surface 8, a proximal end surface 4, and the outer surface 6 of the support layer 7, when engaged.

The conductive double-barrel housing 11 comprises a radially protruding portion 49, connecting the test barrel 12 to the reference barrel 14. The radially protruding portion 49 has approximately the same length as the recessed portion 9 and protrudes radially to the outside. It is configured to hold the reference barrel axis 20 at a radial distance from the longitudinal axis 19. The reference barrel 14 protrudes in a longitudinal direction towards the proximal end 3 of the probe tip 1, leaving a gap which is covered by the insulating double-barrel housing 13. The insulating double-barrel housing 13 covers the radial and proximal-end-facing surfaces of the conductive double-barrel housing 11. On the proximal-end-facing surface, the insulated double-barrel housing 13 comprises a beveled reference opening 51 where the reference signal socket inlet is provided.

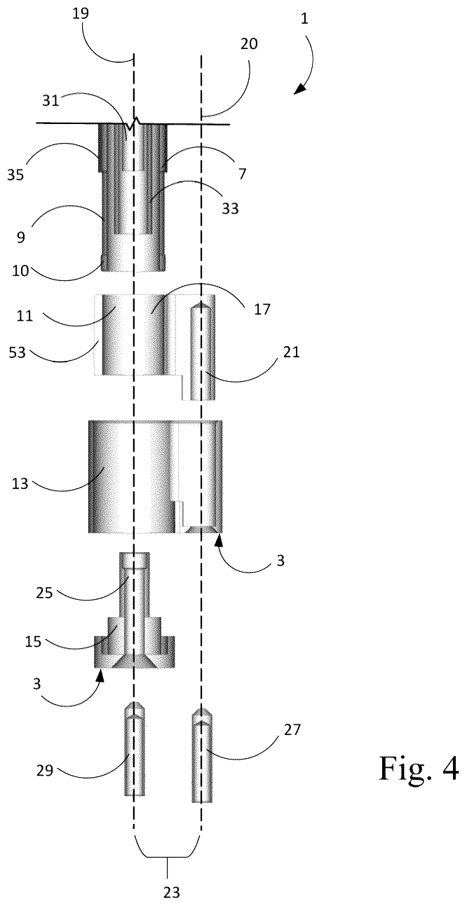

Referring now to FIG. 4, an exemplary probe tip is shown in a cross-sectional side view as a partially exploded view. Starting from the top, the outer layer 35, the support layer 7, the insulation layer 33, and the attenuator device 31 are shown as an assembled stack. This configuration may or may not represent a real configuration before assembling the remaining parts to achieve the probe tip 1 according to the present disclosure.

Shown below the partially assembled stack are the conductive double-barrel housing 11, the insulated double-barrel housing 13, the cap 15, and finally the test socket 29 and the reference socket 27. The through-hole opening 17 of the conductive double-barrel housing 11 is designed to be fitted to the recessed portion 9 of the support layer 7. Mounting the conductive double-barrel housing 11 to the support layer 7 along the longitudinal direction therefore requires overcoming the ring portion 10 of the support layer 7. To achieve this, the conductive double-barrel housing 11 comprises a longitudinal slit 53, allowing to elastically deform the conductive double-barrel housing 11 while it is pushed over the ring portion 10. This way, the conductive double-barrel housing 11 can be mounted to the support layer 7 in an axially secured manner while capable of being revolved around the longitudinal axis 19. Specifically, the test barrel is axially mounted to a recessed portion of the support layer and is rotatable around a longitudinal axis of the support layer. When engaged, the cap 15 is fixed to the support layer 7. In other words, the cap 15 does not revolve with the conductive double-barrel housing 11 and the insulated double-barrel housing 13.

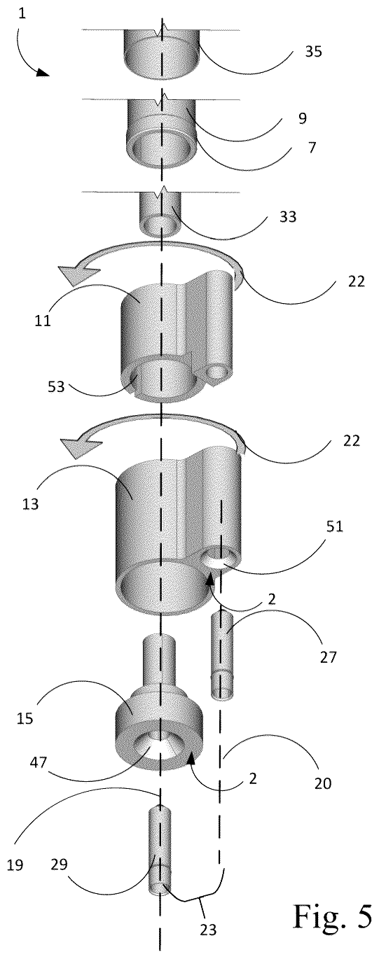

The insulating double-barrel housing 13 may be fitted to the conductive double-barrel housing 11 in an axial direction along the longitudinal axis 19. When engaged, the insulating double-barrel housing 13 is tightly friction-fitted to the conductive double-barrel housing 11. Other than the conductive double-barrel housing 11, the insulating double-barrel housing 13 extends all the way to the proximal end 3 of the probe tip 1. In the open volume below the support layer 7 and the proximal end 3, the cap 15 is received when engaged. The reference socket 27 is received inside the reference receptacle 21 of the conductive double-barrel housing 11 and the test socket 29 is received in the test receptacle 25 of the cap 15. Assembling the adjustable probe tip 1 may be achieved according to the exploded view in FIGS. 4 and 5. However, it may also be achieved by a different sequence, for example by mounting the reference socket 27 to the reference receptacle 21 before assembling the insulating double-barrel housing 13 to the conductive double-barrel housing 11. Further, the insulation layer 33 and the attenuator device 31 may or may not be assembled after the double-barrel housings 11, 13 are mounted to the support layer 7.

Referring now to FIG. 5, an exemplary probe tip is shown in a perspective, exploded view seen from below. The shown illustration shows the longitudinal slit 53 of the conductive double-barrel housing 11. When the conductive double-barrel housing 11 is slid over the ring portion 10 of the support layer 7, the longitudinal slit 53 temporarily widens due to elastic deformation.

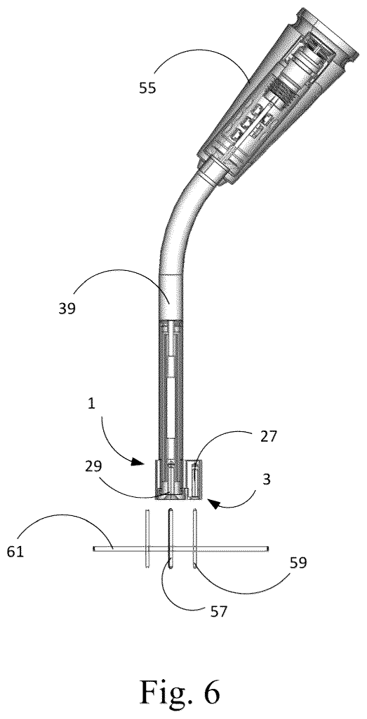

When assembled, the furthermost proximal end surface of the probe tip 1 is shown as the DUT abutment surface 2, which is provided partly by the insulated double-barrel housing 13 and partly by the cap 15. The DUT abutment surface 2 also comprises the beveled test opening 47 and the beveled reference opening 51. When the adjustable probe tip 1 is brought closer to the DUT for engagement with the test and reference pins (shown in FIG. 6) the beveled test opening 47 and the beveled reference opening 51 assist inserting the pins into the reference socket 27 and the test socket 29. This can be achieved by approaching the DUT with a suitably rotated double-barrel housing. When assembled, the conductive double-barrel housing 11 and the insulated double-barrel housing 13 are revolvable about the reference axis 19 along the adjustment angle 22. Since these two components are affixed to one another, both have the same adjustment angle 22. The reference socket 27 also follows the adjustment angle 22 in a constant radius, which is the pitch 23.

The revolving elements may be referred to as double-barrel housing and may comprise conductive double-barrel housing 11, insulating double-barrel housing 13, and reference socket 27 can be easily assembled or disassembled to the reference layer 7. After disassembling cap 15, these components can simply be removed in an axial direction. If a different pitch 23 is needed, the double-barrel housing can simply be replaced with another double-barrel housing having a different pitch 23. After assembling the double-barrel housing to the support layer 7, the double-barrel housing 25 is axially secured by the assembling the cap 15 to the support layer 7.

Referring now to FIG. 6, an exemplary adjustable probe tip in combination with a probe tip cable, a probe head adapter, and a DUT in a disengaged configuration. The adjustable probe tip 1 comprises a probe tip cable 39, which is mounted to a probe head adapter 55. The probe head adapter 55 is configured to be releasably mounted to a probe head (not shown in FIG. 6). On its proximal end 3, the probe tip 1 comprises the insulated double-barrel housing 13, which is shown adjacent to a DUT 61. The DUT 61 comprises several square pins, such as one reference square pin 59 and a signal square pin 57. The adjustable probe tip 1 has been brought in a position where the signal socket 29 aligns with the signal square pin 57. Further, the insulated double-barrel housing 13 has been rotated such that the reference socket 27 aligns with the reference square pin 59. By lowering the adjustable probe tip 1 towards the DUT 61 further, the reference square pin 59 can be inserted into the reference socket 27 and, simultaneously, the signal square pin 57 can be inserted into the signal socket 29. In such an engaged position, a shielded electrical connection between DUT 61 and probe tip 1 can be achieved.

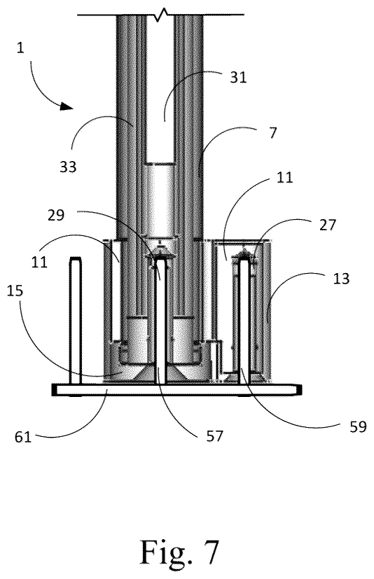

Referring now to FIG. 7, a partial cross-sectional side view of an exemplary adjustable probe tip and a DUT in an engaged configuration is shown. Accordingly, the reference square pin 59 is inserted into the reference socket 27 and the signal square pin 57 is inserted into the signal socket 29. In such an engaged position, a shielded electrical connection between DUT 61 and probe tip 1 is achieved. The reference signal travels from the reference square pin 59 to the reference socket 27, where it is transmitted to the support layer 7 via the conductive double-barrel housing 11. The test signal travels from the signal square pin 57 to the signal socket 29, where it is transmitted to the attenuator device 31.

### CONCLUSION

Although the disclosure has been described in terms of exemplary embodiments, the disclosure is not limited thereto. This description of the exemplary embodiments is set to be understood in connection with the figures of the accompanying drawings, which are to be considered part of the entire written description. Relative terms such as “lower,” “upper,” “horizontal,” “vertical,” “above,” “below,” “up,” “down,” “top,” “bottom,” “back,” and “front” as well as derivatives such as “horizontally,” “downwardly,” and “upwardly,” should be construed to refer to the orientation as then described or as shown in the particular figure under discussion. These relative terms are for convenience of description and do not require that the spacer or spacer assemblies be constructed or operated in a particular orientation. Terms concerning attachments and coupling such as “connected” refer to a relationship wherein structures are secured or attached to one another either directly or indirectly through intervening structures, as well as both movable or rigid attachments or relationships, unless expressly described otherwise.

While this specification contains many specific implementation details, these details should not be construed as limitations on the scope of any disclosures or of what may be claimed. It should be understood that these exemplary embodiments may be susceptible to various modifications and may present in alternative forms. All statements herein reciting principles, aspects, and embodiments of the disclosure are intended to encompass both the structural and the functional equivalents thereof. Additionally, it is intended that such equivalents include both currently known equivalents and any elements developed in the future that perform the same function regardless of structure. The claims are not intended to be limited to the particular embodiments, modifications, and alternative forms disclosed but are intended to cover all modifications, equivalents, and alternatives falling within the spirit and scope of the disclosure.

What is claimed is:

1. An adjustable probe tip, comprising:
a. a support layer having a recessed portion and
b. a double-barrel housing comprising a test barrel and a reference barrel,
wherein the test barrel of the double-barrel housing is axially mounted to the recessed portion of the support layer, and
wherein the test barrel of the double-barrel housing is rotatable around a longitudinal axis of the support layer, and the reference barrel orbits the longitudinal axis in an adjustment angle at a distance equal to a pitch.

2. The adjustable probe tip of claim 1, wherein the double-barrel housing further comprises a longitudinal slit, such that the double-barrel housing can be secured to the recessed portion of the support layer by elastic deformation.

3. The adjustable probe tip of claim 1, further comprising an insulated housing covering the conductive double-barrel housing.

4. The adjustable probe tip of claim 1, further comprising an electrically insulating outer layer.

5. The adjustable probe tip of claim 1, wherein the reference barrel of the double barrel housing comprises a reference socket on a proximal end of the adjustable probe tip, wherein the reference socket establishes a reference signal path to the support layer.

6. The adjustable probe tip of claim 5, wherein the support layer further comprises an internal insulation layer and an attenuator device.

7. The adjustable probe tip of claim 5, further comprising an electrically insulated cap on the proximal end of the adjustable probe tip, and wherein the electrically insulated cap comprises a signal socket to establish a test signal path inside the support layer.

8. The adjustable probe tip of claim 7, further comprising a test signal coupler at a distal end of the adjustable probe tip.

9. The adjustable probe tip of claim 7, wherein the reference socket is arranged parallel to the signal socket.

10. The adjustable probe tip of claim 7, wherein the reference socket and the test socket are shielded.

11. The adjustable probe tip of claim 8, wherein the insulated double-barrel housing comprises a beveled reference opening leading to the reference socket, and wherein the insulated cap comprises a beveled signal opening, leading to the signal socket.

12. The adjustable probe tip of claim 8, wherein the test signal coupler is connected to a probe tip cable.

13. The adjustable probe tip of claim 12, wherein the probe tip cable leads to a probe head adapter.

14. An adjustable probe tip, comprising:
a. a support layer having a recessed portion and
b. a double-barrel housing comprising a test barrel and a reference barrel,
wherein the test barrel of the double-barrel housing is axially mounted to the recessed portion of the support layer,
wherein the test barrel of the double-barrel housing is rotatable around a longitudinal axis of the support layer, and the reference barrel orbits the longitudinal axis in an adjustment angle at a distance equal to a pitch,
wherein the adjustable probe tip is connected to a probe tip cable of a probe head adapter at a distal end of the adjustable probe tip, and
wherein the test barrel comprises a test socket configured to receive a test signal pin of a DUT, and
wherein the reference barrel comprises a reference socket configured to receive a reference signal pin of a DUT.

15. The adjustable probe tip of claim 14, further comprising: the test signal pin inserted into the test socket, and the reference signal pin simultaneously inserted into the reference socket, thereby establishing a shielded electrical connection between the DUT and the adjustable probe tip.
